(19) United States
(12) Patent Application Publication
(10) Pub. No.: US 2026/0122976 A1
(43) Pub. Date: Apr. 30, 2026

(54) METALLOID SOURCE AND DRAIN WITH BACKSIDE CONTACT AND PLUG

(71) Applicant: International Business Machines Corporation, Armonk, NY (US)

(72) Inventors: Dominic Picciocca, Wynantskill, NY (US); Oleg Gluschenkov, Tannersville, NY (US); Yasir Sulehria, Niskayuna, NY (US); Sebastian Howard, Albany, NY (US)

(21) Appl. No.: 18/928,268

(22) Filed: Oct. 28, 2024

(51) Int. Cl. H01L 29/10; H01L 29/06; H01L 29/417; H01L 29/423; H01L 29/775; H01L 29/786

(52) U.S. Cl. CPC H10D 30/751; H10D 30/43; H10D 30/6735; H10D 30/6757; H10D 62/121; H10D 64/254

(57) ABSTRACT

A field effect transistor (FET) structure is provided and includes an FET stack including channels, source/drain (S/D) regions defined on opposite sides of the FET stack, buffers formed of doped semiconductor material disposed in contact with the channels and to protrude into each of the S/D regions, one of epitaxy and a first metalloid disposed in a first one of the S/D regions in contact with corresponding ones of the buffers, a plug disposed in backside contact with the one of epitaxy and the first metalloid, a second metalloid disposed in a second one of the S/D regions in contact with corresponding ones of the buffers, a first metallic contact disposed in frontside contact with the one of epitaxy and the first metalloid and a second metallic contact in backside contact with the second metalloid.

### BACKGROUND

The present disclosure generally relates to fabrication methods and resulting structures for semiconductor devices. More specifically, the present disclosure relates to a field effect transistor (FET) structure of a metalloid source and drain with a backside contact and a plug.

A transistor is a semiconductor device used to amplify or switch electrical signals and power and is one of the basic building blocks of modern electronics. An FET is a type of transistor that uses an electric field to control the flow of current in a semiconductor. An FET has three terminals: a source, a gate and a drain. FETs control the flow of current by the application of a voltage to the gate, which in turn alters the conductivity between the drain and the source.

### SUMMARY

According to an aspect of the disclosure, a field effect transistor (FET) structure is provided and includes an FET stack including channels, source/drain (S/D) regions defined on opposite sides of the FET stack, buffers formed of doped semiconductor material disposed in contact with the channels and to protrude into each of the S/D regions, one of epitaxy and a first metalloid disposed in a first one of the S/D regions in contact with corresponding ones of the buffers, a plug disposed in backside contact with the one of epitaxy and the first metalloid, a second metalloid disposed in a second one of the S/D regions in contact with corresponding ones of the buffers, a first metallic contact disposed in frontside contact with the one of epitaxy and the first metalloid and a second metallic contact in backside contact with the second metalloid. In one or more additional and/or alternative embodiments, the first and second metalloids forms highly conductive contact interfaces with the first and second metallic contacts and highly conductive contact interfaces with the buffers.

According to an aspect of the disclosure, a fabrication method for a field effect transistor (FET) structure is provided and includes etching into a substrate to form cavities in source/drain (S/D) regions defined on opposite sides of an FET stack including channels on the substrate, filling the cavities with plugs, growing buffers formed of doped semiconductor material on the channels to protrude into the S/D regions, filling the S/D regions with epitaxy, masking one of the S/D regions, etching the epitaxy and the one of the plugs in another one of the S/D regions, filling the another one of the S/D regions with a metalloid to be disposed in contact with corresponding ones of the buffers, unmasking the one of the S/D regions, disposing a first metallic contact in frontside contact with the epitaxy and disposing a second metallic contact in backside contact with the metalloid. In one or more additional and/or alternative embodiments, the metalloid forms a highly conductive contact interface with the second metallic contact and highly conductive contact interfaces with the corresponding ones of the buffers.

According to an aspect of the disclosure, a fabrication method for a field effect transistor (FET) structure is provided and includes etching into a substrate to form substrate cavities in source/drain (S/D) regions defined on opposite sides of an FET stack including channels on the substrate, filling the substrate cavities with plugs, growing buffers formed of doped semiconductor material on the channels to protrude into the S/D regions, filling the S/D regions onto the plugs with epitaxy, masking one of the S/D regions, etching the epitaxy and the one of the plugs in another one of the S/D regions, filling the another one of the S/D regions with a metalloid to be disposed in contact with corresponding ones of the buffers, unmasking the one of the S/D regions, disposing a first metallic contact in frontside contact with the epitaxy and disposing a second metallic contact in backside contact with the metalloid. In one or more additional and/or alternative embodiments, the metalloid forms a highly conductive contact interface with the second metallic contact and highly conductive contact interfaces with the corresponding ones of the buffers.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1 is a side schematic view of an FET structure of a semiconductor device with S/D regions filled with metalloids in accordance with one or more embodiments;

FIG. 2 is a flow diagram illustrating a fabrication method for fabricating an FET structure of a semiconductor device with S/D regions filled with metalloids in accordance with one or more embodiments;

FIG. 3 is a side schematic view of an initial stage of assembly of an FET structure with S/D regions filled with buffers and epitaxy in accordance with one or more embodiments;

FIG. 4 is a side schematic view of a second stage of assembly of an FET structure with etched S/D regions in accordance with one or more embodiments;

FIG. 5 is a side schematic view of a third stage of assembly of an FET structure with a masked S/D region and an unmasked S/D region with buffers in accordance with one or more embodiments;

FIG. 6 is a side schematic view of a fourth stage of assembly of an FET structure with a masked S/D region and an unmasked S/D region with buffers and a metalloid in accordance with one or more embodiments;

FIG. 7 is a side schematic view of a fifth stage of assembly of an FET structure with a masked S/D region with buffers and a metalloid and an unmasked S/D region with buffers in accordance with one or more embodiments;

FIG. 8 is a side schematic view of a sixth stage of assembly of an FET structure with a masked S/D region with buffers and a metalloid and an unmasked S/D region with buffers and a metalloid in accordance with one or more embodiments;

FIG. 9 is a side schematic view of an FET structure of a semiconductor device with S/D regions filled with metalloids and contacts disposed in contact with the metalloids in accordance with one or more embodiments;

FIG. 10 is a side schematic view of an FET structure of a semiconductor device with an S/D region filled with a metalloid and a backside metallic contact in accordance with one or more embodiments;

FIG. 11 is a side schematic view of an FET structure of a semiconductor device with an S/D region filled with a metalloid, a backside metallic contact and a plug in accordance with one or more embodiments;

FIG. 12 is a flow diagram illustrating a fabrication method for fabricating the FET structure of FIG. 10 in accordance with one or more embodiments;

FIG. 13 includes side schematic views graphically illustrating a portion of the fabrication method of FIG. 12 in accordance with one or more embodiments;

FIG. 14 is a flow diagram illustrating a fabrication method for fabricating the FET structure of FIG. 11 in accordance with one or more embodiments;

FIG. 15 includes side schematic views graphically illustrating a portion of the fabrication method of FIG. 14 in accordance with one or more embodiments;

FIG. 16 is a side schematic view of an FET structure of a semiconductor device with an S/D region filled with a metalloid, a backside metallic contact and a frontside metallic contact in accordance with one or more embodiments; and

FIG. 17 includes side schematic views graphically illustrating formation of a backside metallic contact of an FET structure of a semiconductor device with an S/D region filled with a metalloid in accordance with one or more embodiments.

The diagrams depicted herein are illustrative. There can be many variations to the diagram or the operations described therein without departing from the spirit of the disclosure. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

According to an aspect of the disclosure, a field effect transistor (FET) structure is provided and includes an FET stack including channels, source/drain (S/D) regions defined on opposite sides of the FET stack, buffers formed of doped semiconductor material disposed in contact with the channels and to protrude into each of the S/D regions, one of epitaxy and a first metalloid disposed in a first one of the S/D regions in contact with corresponding ones of the buffers, a plug disposed in backside contact with the one of epitaxy and the first metalloid, a second metalloid disposed in a second one of the S/D regions in contact with corresponding ones of the buffers, a first metallic contact disposed in frontside contact with the one of epitaxy and the first metalloid and a second metallic contact in backside contact with the second metalloid. In one or more additional and/or alternative embodiments, the first and second metalloids forms highly conductive contact interfaces with the first and second metallic contacts and highly conductive contact interfaces with the buffers.

In accordance with one or more additional embodiments, the first and second metalloids are reflowable, the first and second metalloids are conductive and the first and second metalloids are non-miscible with and do not form a silicide with the doped semiconductor material such that the metalloid can fill the S/D region and form the highly conductive contact interface with the buffers.

In accordance with one or more additional embodiments, the doped semiconductor materials of the buffers are doped with one of first and second dopants and the first and second metalloids each include one or more of a group III material, a group IV material and a group V material depending on the particular application and design requirements.

In accordance with one or more additional embodiments, the doped semiconductor materials of the buffers are doped with one of first and second dopants and the first and second metalloids each include one or more of tin, tin alloy, antimony, aluminum-based compounds, aluminum diboride and indium depending on the particular application and design requirements.

In accordance with one or more additional embodiments, the plug includes a low-k dielectric to protect against a short circuit with the second metallic contact.

In accordance with one or more additional embodiments, the plug includes silicon-germanium to protect against a short circuit with the second metallic contact.

In accordance with one or more additional embodiments, the first and second metallic contacts each include an elemental metal that is highly conductive.

In accordance with one or more additional embodiments, the second metallic contact forms a wrap-around backside contact with the second metalloid to increase a surface area of the backside contact.

In accordance with one or more additional embodiments, the FET structure further includes a low-k dielectric and a dielectric liner interposed between the low-k dielectric and a frontside of the second metalloid and a contact liner interposed between the one of the epitaxy and the first metalloid and the first metallic contact to electrically insulate the frontside of the second metalloid and to increase conductivity between the one of the epitaxy and the first metalloid and the first metallic contact.

According to an aspect of the disclosure, a fabrication method for a field effect transistor (FET) structure is provided and includes etching into a substrate to form cavities in source/drain (S/D) regions defined on opposite sides of an FET stack including channels on the substrate, filling the cavities with plugs, growing buffers formed of doped semiconductor material on the channels to protrude into the S/D regions, filling the S/D regions with epitaxy, masking one of the S/D regions, etching the epitaxy and the one of the plugs in another one of the S/D regions, filling the another one of the S/D regions with a metalloid to be disposed in contact with corresponding ones of the buffers, unmasking the one of the S/D regions, disposing a first metallic contact in frontside contact with the epitaxy and disposing a second metallic contact in backside contact with the metalloid. In one or more additional and/or alternative embodiments, the metalloid forms a highly conductive contact interface with the second metallic contact and highly conductive contact interfaces with the corresponding ones of the buffers.

In accordance with one or more additional embodiments, the filling includes reflowing the metalloid to completely fill the first and second S/D regions.

In accordance with one or more additional embodiments, the doped semiconductor materials of the buffers are doped with one of first and second dopants and the metalloid includes one or more of a group III material, a group IV material and a group V material depending on the particular application and design requirements.

In accordance with one or more additional embodiments, the doped semiconductor materials of the buffers are doped with one of first and second dopants and the metalloid includes one or more of tin, tin alloy, antimony, aluminum-based compounds, aluminum diboride and indium depending on the particular application and design requirements.

In accordance with one or more additional embodiments, the plugs include a low-k dielectric to protect against short circuits.

In accordance with one or more additional embodiments, the plugs include silicon-germanium to protect against short circuits.

In accordance with one or more additional embodiments, the fabrication method further includes depositing a liner in a contact trench at a frontside of the metalloid and filling a remainder of the contact trench with low-k dielectric material to electrically insulate the frontside of the metalloid.

In accordance with one or more additional embodiments, the disposing of the first metallic contact in the frontside contact with the epitaxy includes depositing a conductive liner in a contact trench at a frontside of the epitaxy and filling the contact trench with an elemental metal to form an elemental metallic contact to increase conductivity between the epitaxy and the elemental metal.

In accordance with one or more additional embodiments, the disposing of the second metallic contact in the backside contact with the metalloid includes forming a wrap-around backside contact with the metalloid increase a surface area of the backside contact.

In accordance with one or more additional embodiments, the disposing of the second metallic contact in the backside contact with the metalloid includes replacing the substrate with a new material, etching the new material to form a cavity exposing a backside end of the metalloid and filling the cavity with an elemental metal to form an elemental metal contact that is highly conductive.

According to an aspect of the disclosure, a fabrication method for a field effect transistor (FET) structure is provided and includes etching into a substrate to form substrate cavities in source/drain (S/D) regions defined on opposite sides of an FET stack including channels on the substrate, filling the substrate cavities with plugs, growing buffers formed of doped semiconductor material on the channels to protrude into the S/D regions, filling the S/D regions onto the plugs with epitaxy, masking one of the S/D regions, etching the epitaxy and the one of the plugs in another one of the S/D regions, filling the another one of the S/D regions with a metalloid to be disposed in contact with corresponding ones of the buffers, unmasking the one of the S/D regions, disposing a first metallic contact in frontside contact with the epitaxy and disposing a second metallic contact in backside contact with the metalloid. In one or more additional and/or alternative embodiments, the metalloid forms a highly conductive contact interface with the second metallic contact and highly conductive contact interfaces with the corresponding ones of the buffers.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the disclosure, in conventional FET structures of semiconductor devices, a nanosheet FET stack is provided with nanosheets forming channels between buffers in source/drain (S/D) regions, such as p-doped (PFET) and n-doped (NFET) regions. These S/D regions can be capped by a metallic contact. In one FET structure type, the S/D regions are metallic and fill in the S/D regions around the buffers. In these cases, the metallic material of the S/D regions provide good vertical conductivity and make low-resistance and highly conductive metal-metal contact interfaces with the metallic contacts. A problem is that the metallic material of the S/D regions forms a silicide with the buffers and creates a contact interface with high interfacial resistivity and poor conduction. In another FET structure type, the S/D regions are formed of highly doped semiconductor material and fill in the S/D regions around the buffers. In these cases, the highly doped semiconductor material of the S/D regions provides for low interfacial resistivity and good conduction with the buffers. On the other hand, the highly-doped semiconductor material of the S/D regions does not provide for good vertical conductivity and makes highly resistive contact interfaces with poor conductivity with the metallic contacts.

Turning now to an overview of the aspects of the disclosure, one or more embodiments of the disclosure address the above-described shortcomings of the prior art by providing an FET structure of a semiconductor device with channels and S/D regions. The FET structure includes heavily doped semiconductor material adjacent to each of the channels, a metalloid adjacent to the heavily doped semiconductor material and metallic contacts disposed in contact with the metalloid. The metalloid in FET structure provides for low interfacial resistance and good conductivity in the contact interfaces with the contacts and the heavily doped semiconductor material as well as good vertical conductivity.

The above-described aspects of the disclosure address the shortcomings of the prior art by providing a semiconductor device FET structure that includes an FET stack including channels, first and second S/D regions defined on opposite sides of the FET stack, first and second buffers formed of doped semiconductor material disposed in contact with the channels and to protrude into the first and second S/D regions, respectively, first and second metalloids disposed in remainders of each of the first and second S/D regions, respectively, around and in contact with the first and second buffers, respectively, and first and second metallic contacts. The first and second metallic contacts are disposed over the first and second S/D regions, respectively, and in contact with the first and second metalloids, respectively.

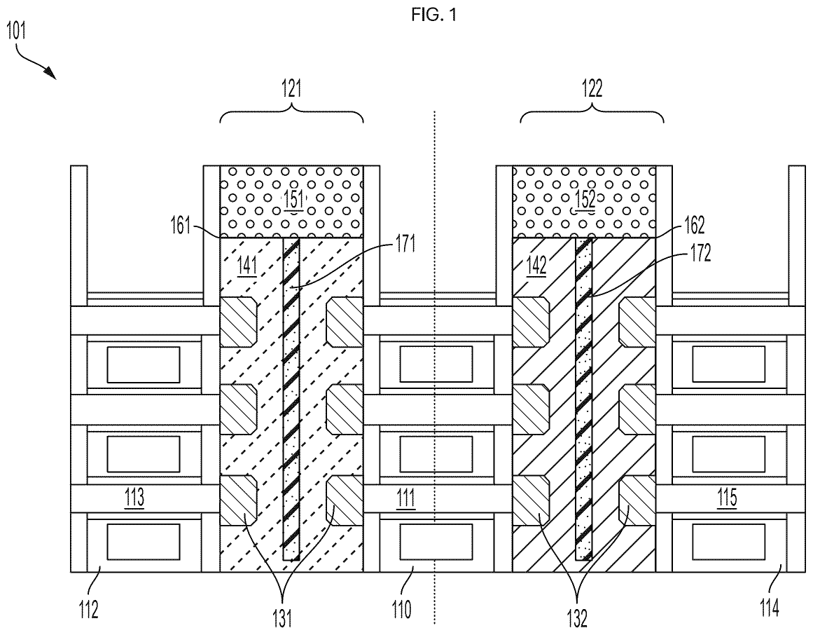

With reference to FIG. 1, an FET structure 101 of a semiconductor device is provided and includes a center FET stack 110 including channels 111, a first additional FET stack 112 that includes channels 113 and a second additional FET stack 114 that includes channels 115. The center FET stack 110 is sandwiched, though not necessarily with immediate adjacency, between the first and second additional FET stacks 112 and 114 with first S/D region 121 defined between the center FET stack 110 and the first additional FET stack 112 and with second S/D region 122 defined between the center FET stack 110 and the second additional FET stack 114. The first S/D region 121 can be provided as a source and/or p-doped FET (PFET) region and the second S/D region 122 can be provided as a drain and/or n-doped FET (NFET) region. The center FET stack 110, the first additional FET stack 112 and the second additional FET stack 114 can each be configured as nanosheet FET structures with nanosheets forming the channels 111, 113 and 115.

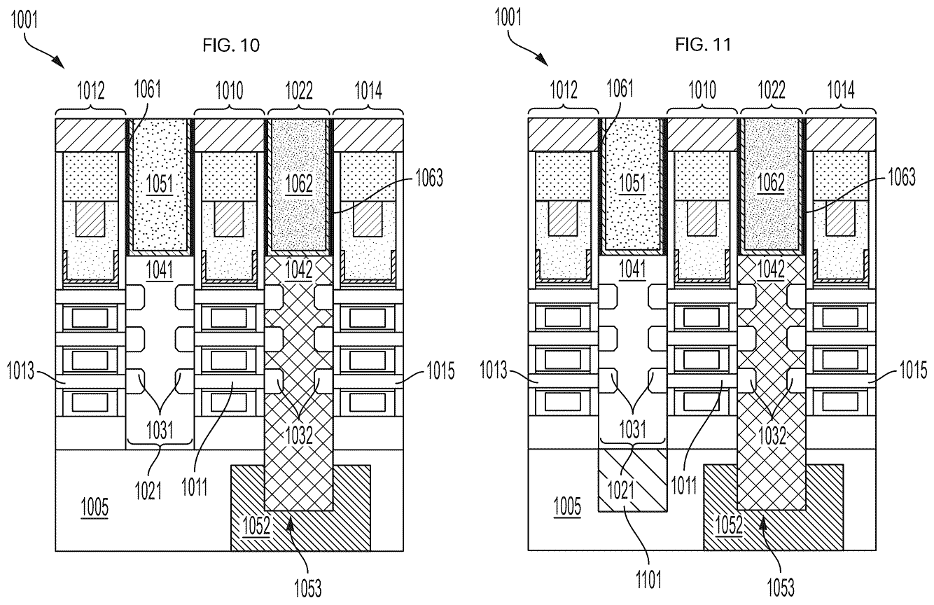

It is to be understood that the center FET stack 110 is not necessarily physically sandwiched between n-and p-type devices. In practice, the n/p-type devices would tend to be separated. For ease of illustration, p and n devices are being shown together to illustrate that process flow allows for different metalloid materials based on device type within a same substrate. The dashed line down the center of FIG. 1 indicates that the halves of the drawing of FIG. 1 are actually parts of potentially separate structures. It is to be further understood that this applies to at least the embodiments of FIGS. 1-9 and to the embodiments of FIGS. 10-17, which can also be generally understood to depict single device structures in which both S/D regions can include same or similar material types (p/n) whether they are metalloid or epitaxy-based materials.

It is to be further understood that, in accordance with one or more embodiments, the center FET stack 110 and the first additional FET stack 112 can be provided as one FET type and/or the center FET stack 110 and the second additional FET stack 114 can be provided as a different FET type. Alternatively, the center stack 110 can be provided as one FET type.

The FET structure 101 further includes first buffers 131 and second buffers 132, a first metalloid 141 and a second metalloid 142, a first metallic contact 151 and a second metallic contact 152. The first buffers 131 are formed of doped semiconductor material and are disposed in contact with the channels 111 and 113 and to protrude into the first S/D region 121. The second buffers 132 are formed of doped semiconductor material and are disposed in contact with the channels 111 and 115 and to protrude into the second S/D region 122. The doped semiconductor material of the first buffers 131 can be doped with a first dopant and the doped semiconductor material of the second buffers 132 can be doped with a second dopant that is different from the first dopant (i.e., silicon doped with boron for the first buffers 131 and silicon doped with phosphorous for the second buffers 132). The first metalloid 141 is disposed in the first S/D region 121 in contact with the first buffers 131. The second metalloid 142 is disposed in the second S/D region 122 in contact with the second buffers 132. The first metallic contact 151 is disposed over the first S/D region 121 in contact with the first metalloid 141. The second metallic contact 152 is disposed over the second S/D region 122 in contact with the second metalloid 142. The first and second metallic contacts 151 and 152 can be provided as metallic material, such as an elemental metal.

It is to be understood that the term “metalloid,” as used herein, can refer to any of various metalloids, metalloid compounds and metalloid alloys. The use of the term “metalloid” in this description and the following claims is for clarity and brevity and should not be interpreted as limiting the description or the claims in any way.

The first and second metalloids 141 and 142 are reflowable, which allows the first and second metalloids 141 and 142 to be flown into the first and second S/D regions 121 and 122 and around and about the first and second buffers 131 and 132, respectively, to ensure that all of the space within the first and second S/D regions 121 and 122 is taken up and to ensure that good electrical contact is made between the first and second metalloids 141 and 142 and the first and second buffers 131 and 132, respectively. The first and second metalloids 141 and 142 are conductive (i.e., vertically conductive) and make good contact interfaces with low resistivity and high conductivity with the first and second metallic contacts 151 and 152, respectively. The vertical conductivity of the first and second metalloids 141 and 142 provides for high electron mobility along a height direction of the first and second S/D regions 121 and 122 and for each of the channels 111, 113 and 115. The first and second metalloids 141 and 142 are also non-miscible with and do not form a silicide with the doped semiconductor material of the first and second buffers 131 and 132, respectively.

It is to be understood that the first and second metalloids 141 and 142 can be provided as a same material or as different materials.

The use of the first and second metalloids 141 and 142 provides for multiple advantages and improvements over conventional structures. For example, whereas metallic material forms a silicide with the doped semiconductor material of the first and second buffers 131 and 132 which makes for high resistivity and low conductivity contact interfaces with buffer layers and with metallic contacts, the first and second metalloids 141 and 142 are non-miscible with and do not form a silicide with the doped semiconductor material of the first and second buffers 131 and 132, respectively, such that the first and second metalloids 141 and 142 make good contact interfaces with low resistivity and high conductivity with the first and second buffers 131 and 132, respectively, and with the first and second metallic contacts 151 and 152, respectively. In addition, the good vertical conductivity of the first and second metalloids 141 and 142 does not represent a significant drawback as compared to vertical conductivity of metal and does provide a significant advantage of vertical conductivity over doped semiconductor material.

In accordance with embodiments, the first and second metalloids 141 and 142 can each include one or more of a group III material, a group IV material and a group V material and can, but are not required to, differ from one another. In some cases, the first and second metalloids can include tin and/or tin alloys, similar materials and/or combinations thereof. In accordance with further embodiments, the first and second metalloids 141 and 142 can each include one or more of tin, tin alloy, antimony, aluminum-based compounds, aluminum diboride and indium and can, but are not required to, differ from one another. It is to be understood that the choice of materials for the first and second metalloids 141 and 142 can inform one another, such that a certain first metalloid 141 might be paired with a same or a different second metalloid 142.

With continued reference to FIG. 1, the FET structure 101 can further include at least one of a first contact liner 161, which is interposed between the first metalloid 141 and the first metallic contact 151 to provide for a contact interface with improved conductivity and reduced resistivity, and a second contact liner 162, which is interposed between the second metalloid 142 and the second metallic contact 152 to provide for a contact interface with improved conductivity and reduced resistivity. In addition, in accordance with one or more additional embodiments, the FET structure 101 can also include at least one of a first vertical post 171, which is formed of metallic material and which extends vertically from the first metallic contact 151 and through the first metalloid 141 to improve vertical conductivity of the first S/D region 121, and a second vertical post 172, which is formed of metallic material and which extends vertically from the second metallic contact 152 and through the second metalloid 142 to improve vertical conductivity of the second S/D region 122.

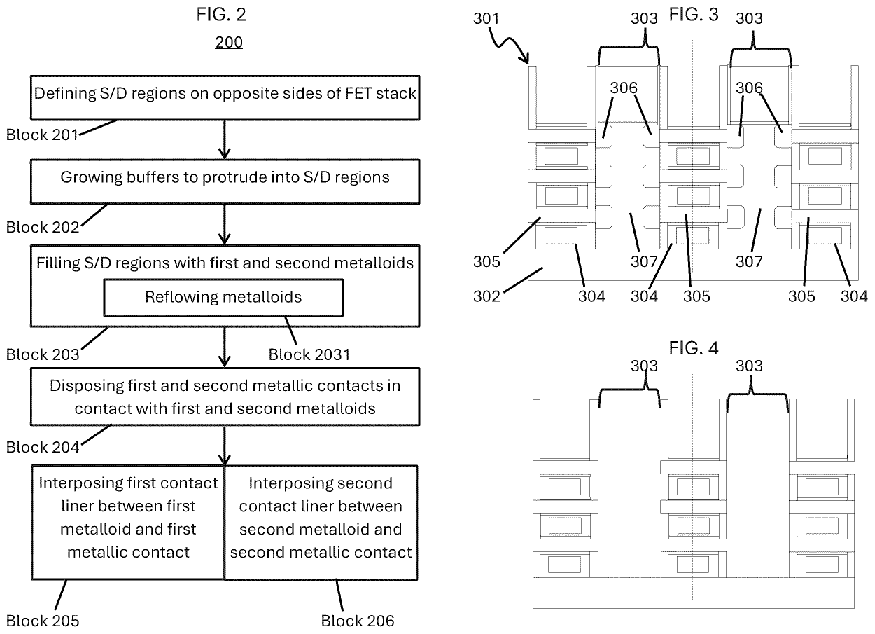

With continued reference to FIG. 1 and with additional reference to FIG. 2, a fabrication method 200 is provided for fabricating an FET structure of a semiconductor device, such as the FET structure 101 of FIG. 1. As shown in FIG. 2, the fabrication method 200 includes defining first and second S/D regions on opposite sides of an FET stack including channels (block 201), growing first and second buffers formed of doped semiconductor material on the channels to protrude into the first and second S/D regions, respectively (block 202), filling the first and second S/D regions with first and second metalloids, respectively, in contact with the first and second buffers, respectively (block 203) and disposing first and second metallic contacts over the first and second S/D regions, respectively, and in contact with the first and second metalloids, respectively (block 204). The filling of block 203 can be executed by reflowing the first and second metalloids (block 2031) and the method 200 can further include at least one of interposing a first contact liner between the first metalloid and the first metallic contact prior to formation of a metal-metalloid contact (block 205) and interposing a second contact liner between the second metalloid and the second metallic contact prior to formation of a metal-metalloid contact (block 206).

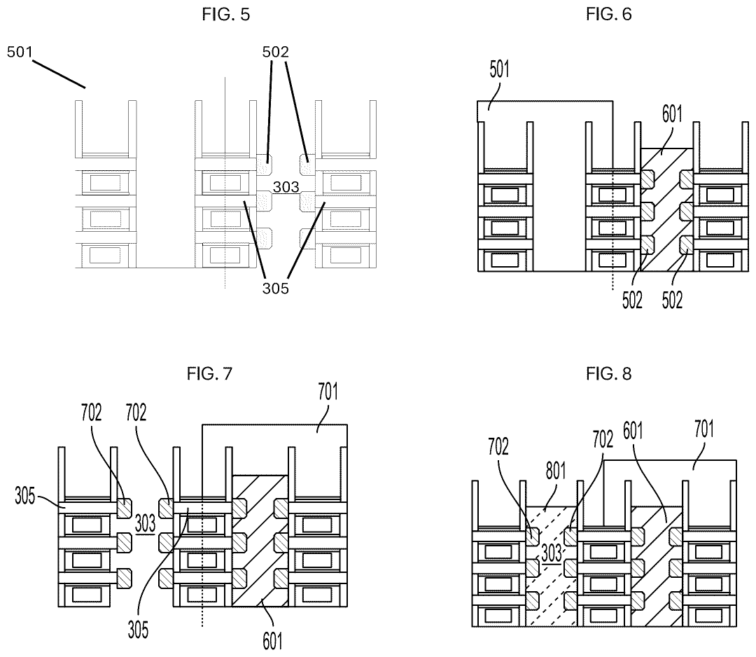

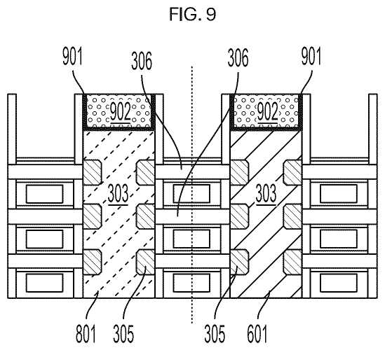

With continued reference to FIG. 2 and with additional reference to FIGS. 3-9, the method 200 of FIG. 2 will now be described further. As shown in FIG. 3, a wafer 301 is built on a substrate 302 to a contact open stage with S/D regions 303 that are interleaved between FET stacks 304 including channels 305, buffers 306 that can be formed of doped semiconductor material and S/D material 307 that can be different from the doped semiconductor material of the buffers 306. As shown in FIGS. 3 and 4, the S/D material 307 is etched out of the S/D regions 303 and then the buffers 306 are optionally etched out of the S/D regions 303. As shown in FIG. 5, a first side (i.e., a PFET side) is masked with a block mask 501 and, assuming the buffers 306 were previously etched out, buffers 502 formed of doped semiconductor material are grown on the channels 305 to protrude into the (unmasked) S/D region 303. As shown in FIG. 6, a metalloid 601 is filled into the empty space of the (unmasked) S/D region 303 by a reflow process, for example, to be disposed in contact with the buffers 502. As shown in FIG. 7, the block mask 501 is removed and a second side (i.e., an NFET side) is masked with a block mask 701 and, again assuming the buffers 306 were previously etched out, buffers 702 formed of doped semiconductor material are grown on the channels 305 to protrude into the (unmasked) S/D region 303. As shown in FIG. 8, a metalloid 801 is filled into the empty space of the (unmasked) S/D region 303 by a reflow process, for example, to be disposed in contact with the buffers 702. As shown in FIG. 9, the block mask 701 is removed, optional contact liners 901 are optionally grown on the metalloids 601 and 801 in the S/D regions 303, and metallic contacts 902 are then formed on the optional contact liners 901 or the metalloids 601 and 801 from an elemental metal, for example.

With reference to FIG. 10, an FET structure 1001 is provided and is generally similar to the FET structure 101 of FIG. 1 with certain additional features. The FET structure 1001 includes a substrate 1005, such as a carrier substrate, a center FET stack 1010 including channels 1011, a first additional FET stack 1012 that includes channels 1013 and a second additional FET stack 1014 that includes channels 1015. The center FET stack 1010, the first additional FET stack 1012 and the second additional FET stack 1014 are disposed on the substrate 1005. The center FET stack 1010 is sandwiched, though not necessarily with immediate adjacency, between the first and second additional FET stacks 1012 and 1014 with first S/D region 1021 defined between the center FET stack 1010 and the first additional FET stack 1012 and with second S/D region 1022 defined between the center FET stack 1010 and the second additional FET stack 1014. The first S/D region 1021 can be provided as a source and/or p-doped FET (PFET) region and the second S/D region 1022 can be provided as a drain and/or n-doped FET (NFET) region. The center FET stack 1010, the first additional FET stack 1012 and the second additional FET stack 1014 can each be configured as nanosheet FET structures with nanosheets forming the channels 1011, 1013 and 1015.

It is to be understood that the center FET stack 1010 is not necessarily physically sandwiched between n-and p-type devices. In practice, the n/p-type devices would tend to be separated as explained above with reference to FIG. 1.

It is to be further understood that, in accordance with one or more embodiments, the center FET stack 1010 and the first additional FET stack 1012 can be provided as one FET type and/or the center FET stack 1010 and the second additional FET stack 1014 can be provided as a different FET type. Alternatively, the center stack 1010 can be provided as one FET type.

The FET structure 1001 further includes first buffers 1031 and second buffers 1032, one of epitaxy and a first metalloid 1041 and a second metalloid 1042, a first metallic contact 1051 and a second metallic contact 1052. The first buffers 1031 are formed of doped semiconductor material and are disposed in contact with the channels 1013 and to protrude into the first S/D region 1021. The second buffers 1032 are formed of doped semiconductor material and are disposed in contact with the channels 1015 and to protrude into the second S/D region 1022. The doped semiconductor material of the first buffers 1031 can be doped with a first dopant and the doped semiconductor material of the second buffers 1032 can be doped with a second dopant that is different from the first dopant (i.e., silicon doped with boron for the first buffers 1031 and silicon doped with phosphorous for the second buffers 1032). The one of the epitaxy and the first metalloid 1041 is disposed in the first S/D region 1021 in contact with the first buffers 1031. A backside of the one of the epitaxy and the first metalloid 1041 can be coplanar with an upper surface of the substrate 1005. The second metalloid 1042 is disposed in the second S/D region 1022 in contact with the second buffers 1032. A backside of the second metalloid 1042 and the second S/D region 1022 can protrude into the substrate 1005 such that the backside of the second metalloid 1042 and the second S/D region 1022 are below the upper surface of the substrate 1005. The first metallic contact 1051 is disposed in frontside contact with the one of the epitaxy and the first metalloid 1041 over the first S/D region 1021. The second metallic contact 1052 is disposed in backside contact with the second metalloid 1042 at the backside of the second metalloid 1042 and the second S/D region 1022. In accordance with embodiments, the second metallic contact 1052 can form a wrap-around backside contact 1053 with multiple surfaces of the backside of the second metalloid 1042. The first and second metallic contacts 1051 and 1052 can be provided as metallic material, such as elemental metal.

With the second metallic contact 1052 disposed in the backside contact with the second metalloid 1042 at the backside of the second metalloid 1042 and the second S/D region 1022, the second metallic contact 1052 is disposed for connection to a backside power distribution network (BSPDN).

The following description will generally refer to the embodiments in which the one of the epitaxy and the first metalloid 1041 is the first metalloid. This is being done for clarity and brevity, and should not be interpreted as limiting the description or the claims in any way.

The first and second metalloids 1041 and 1042 are reflowable, which allows the first and second metalloids 1041 and 1042 to be flown into the first and second S/D regions 1021 and 1022 and around and about the first and second buffers 1031 and 1032, respectively, to ensure that all of the space within the first and second S/D regions 1021 and 1022 is taken up and to ensure that good electrical contact is made between the first and second metalloids 1041 and 1042 and the first and second buffers 1031 and 1032, respectively. The first and second metalloids 1041 and 1042 are conductive (i.e., vertically conductive) and make good contact interfaces with low resistivity and high conductivity with the first and second metallic contacts 1051 and 1052, respectively. The vertical conductivity of the first and second metalloids 1041 and 1042 provides for high electron mobility along a height direction of the first and second S/D regions 1021 and 1022 and for each of the channels 1011, 1013 and 1015. The first and second metalloids 1041 and 1042 are also non-miscible with and do not form a silicide with the doped semiconductor material of the first and second buffers 1031 and 1032, respectively.

It is to be understood that the first and second metalloids 1041 and 1042 can be provided as a same material or as different materials.

The use of the first and second metalloids 1041 and 1042 provides for multiple advantages and improvements over conventional structures. For example, whereas metallic material forms a silicide with the doped semiconductor material of the first and second buffers 1031 and 1032 which makes for high resistivity and low conductivity contact interfaces with buffer layers and with metallic contacts, the first and second metalloids 1041 and 1042 are non-miscible with and do not form a silicide with the doped semiconductor material of the first and second buffers 1031 and 1032, respectively, such that the first and second metalloids 1041 and 1042 make good contact interfaces with low resistivity and high conductivity with the first and second buffers 1031 and 1032, respectively, and with the first and second metallic contacts 1051 and 1052, respectively. In addition, the good vertical conductivity of the first and second metalloids 1041 and 1042 does not represent a significant drawback as compared to vertical conductivity of metal and does provide a significant advantage of vertical conductivity over doped semiconductor material.

In accordance with embodiments, the first and second metalloids 141 and 142 can each include one or more of a group III material, a group IV material and a group V material and can, but are not required to, differ from one another. In some cases, the first and second metalloids can include tin and/or tin alloys, similar materials and/or combinations thereof. In accordance with further embodiments, the first and second metalloids 141 and 142 can each include one or more of tin, tin alloy, antimony, aluminum-based compounds, aluminum diboride and indium and can, but are not required to, differ from one another. It is to be understood that the choice of materials for the first and second metalloids 141 and 142 can inform one another, such that a certain first metalloid 141 might be paired with a same or a different second metalloid 142.

With continued reference to FIG. 10, the FET structure 1001 can further include a contact liner 1061, which is interposed between the first metalloid 1041 and the first metallic contact 1051 to provide for a contact interface with improved conductivity and reduced resistivity, a low-k dielectric material 1062 and a dielectric liner 1063, which is interposed between a frontside of the second metalloid 1042 and the low-k dielectric material 1062. The low-k dielectric material 1062 can be configured to form an air gap or voided region.

With continued reference to FIG. 10 and with additional reference to FIG. 11, the FET structure 1001 of FIG. 10 can further include a plug 1101 disposed in backside contact with the backside of the first metalloid 1041. An upper surface of the plug 1101 can be coplanar with the upper surface of the substrate 1005. The plug 1101 can include a low-k dielectric and, in accordance with one or more embodiments, the plug 1101 can include silicon-germanium. In any case, in an event of misalignment, the presence of the plug 1101 can prevent an occurrence of a source-drain short via the second metallic contact 1052.

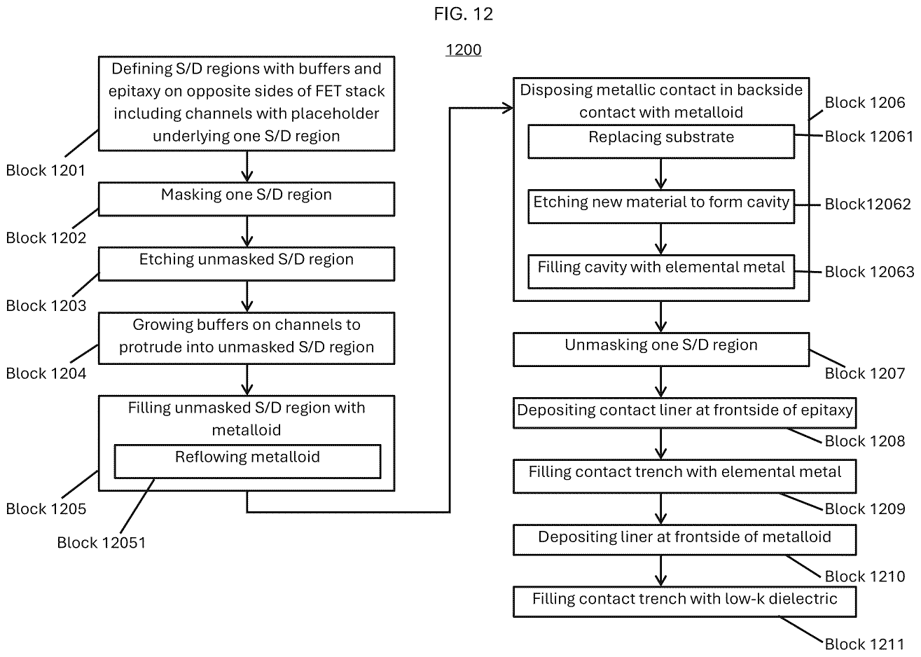

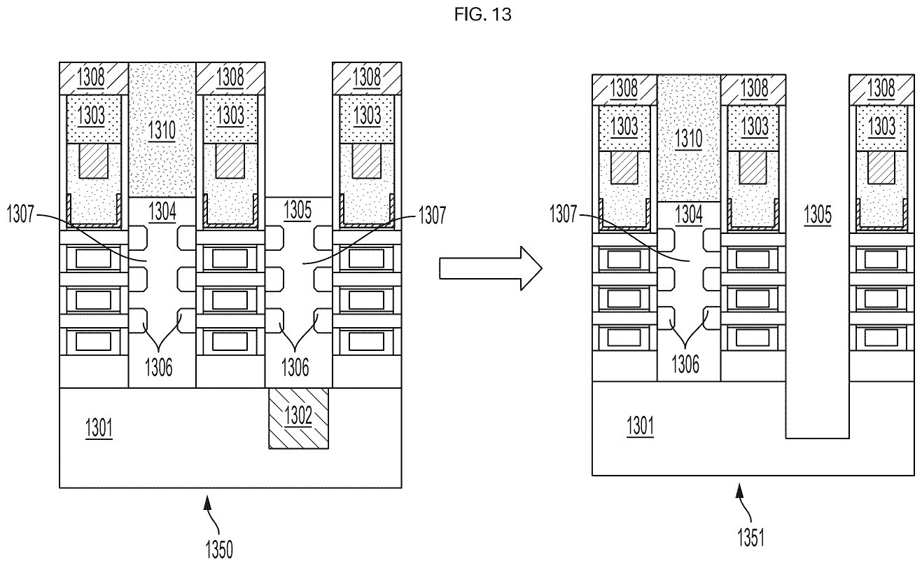

With reference back to FIG. 10 and with additional reference to FIGS. 12 and 13, a fabrication method 1200 is provided for fabricating an FET structure of a semiconductor device, such as the FET structure 1001 of FIG. 10. The fabrication method 1200 includes an initial etching operation executed with respect to a structure similar to what is shown in FIG. 4, which forms a recess in an underlying substrate, and a subsequent formation of a placeholder in the recess. As shown in FIG. 12, the fabrication method 1200 includes defining S/D regions with buffers and epitaxy on opposite sides of an FET stack including channels with the placeholder underlying one of the S/D regions (block 1201), masking one of the S/D regions, such as the one of the S/D regions without the underlying placeholder (block 1202) and etching an unmasked one of the S/D regions into the substrate on which the FET stack is disposed to thereby remove the epitaxy and the placeholder (block 1203).

The masking of block 1202 and the etching of block 1203 are illustrated in FIG. 13. As shown in the left-side image 1350 of FIG. 13, substrate 1301 includes a recess in which placeholder 1302 is disposed, FET stacks 1303 are formed on the substrate 1301 to define S/D regions 1304 and 1305 with buffers 1306 and epitaxy 1307 and CA contacts 1308 are formed on the FET stacks 1303. A mask 1310 is disposed over S/D region 1304, leaving the other S/D region 1304 unmasked. As shown in the right-side image 1351 of FIG. 13, the epitaxy 1307 of the S/D region 1305 and the placeholder 1302 are removed

### By Etching.

As shown in FIG. 12, the fabrication method 1200 can further include growing buffers formed of doped semiconductor material on the channels to protrude into the unmasked one of the S/D regions (block 1204), filling the unmasked one of the S/D regions with a metalloid to be disposed in contact with corresponding ones of the buffers formed in block 1204 (block 1205) and disposing a metallic contact in backside contact with the metalloid (block 1206) as described above with reference to FIG. 10. The fabrication method 1200 can also include unmasking the one of the S/D regions to expose the epitaxy therein (block 1207), depositing a conductive liner in a contact trench at a frontside of the epitaxy (block 1208) and filling a remainder of the contact trench with an elemental metal to form an elemental metallic contact at the frontside of the epitaxy (block 1209) as well as depositing a liner in a contact trench at a frontside of the metalloid (block 1210) and filling a remainder of the contact trench with low-k dielectric material (block 1211).

The filling of block 1205 can be executed by reflowing the metalloid (block 12051). The disposing of the metallic contact in the backside contact with the metalloid of block 1206 can include forming a wrap-around backside contact with the metalloid by replacing the substrate with a new material, such as a carrier substrate (block 12061), etching the new material to form a cavity exposing multiple surfaces of a backside end of the metalloid (block 12062) and filling the cavity with an elemental metal to form an elemental metallic contact (block 12063).

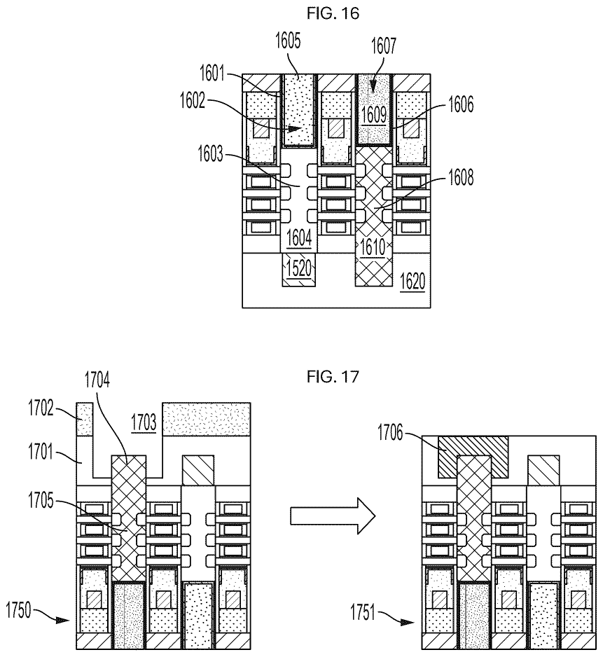

The depositing of the conductive liner of block 1208, the filling of the remainder of the contact trench with the elemental metal to form the elemental metallic contact of block 1209, the depositing of the liner in the contact trench at the frontside of the metalloid of block 1210, filling of the remainder of the contact trench with the low-k dielectric material of block 1211 and the processes associated with the disposing of the metallic contact in the backside contact with the metalloid of block 1206 will be described further below with reference to FIGS. 16 and 17.

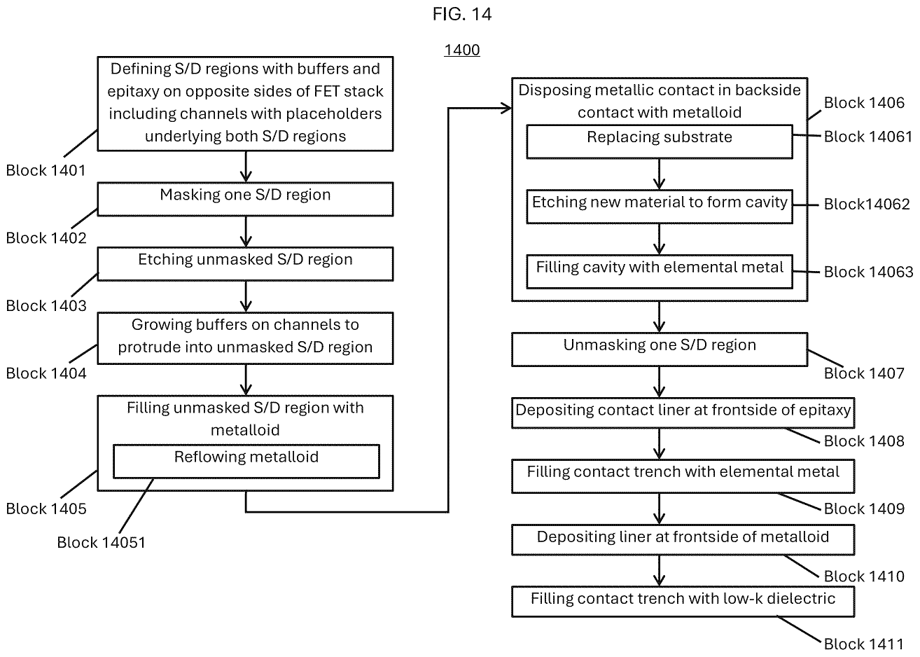

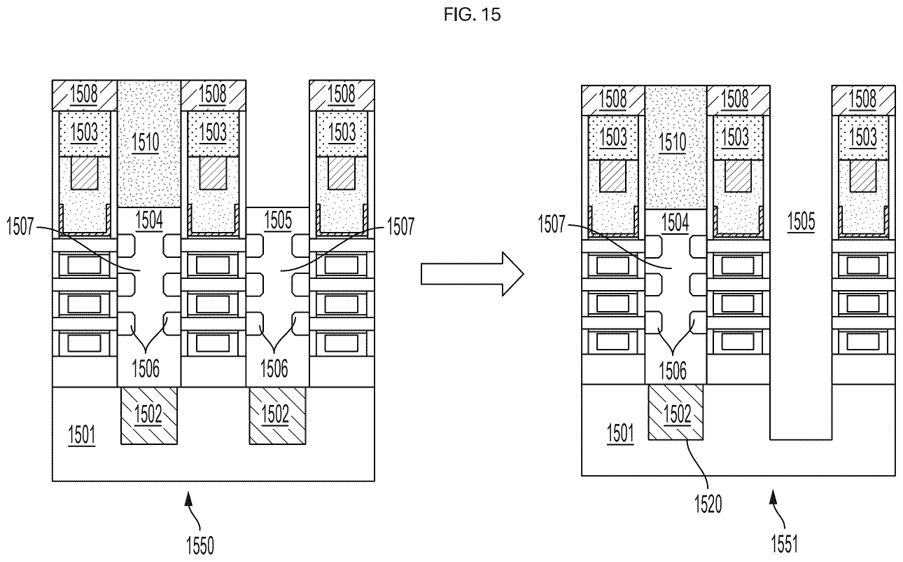

With reference back to FIG. 11 and with additional reference to FIGS. 14 and 15, a fabrication method 1400 is provided for fabricating an FET structure of a semiconductor device, such as the FET structure 1001 of FIG. 11. The fabrication method 1400 includes an initial etching operation executed with respect to a structure similar to what is shown in FIG. 4, which forms recesses in an underlying substrate, and subsequent formation of placeholders in the recesses. As shown in FIG. 14, the fabrication method 1400 includes defining S/D regions with buffers and epitaxy on opposite sides of an FET stack including channels with the placeholders underlying the S/D regions (block 1401), masking one of the S/D regions (block 1402) and etching an unmasked one of the S/D regions into the substrate on which the FET stack is disposed to thereby remove the epitaxy and the corresponding placeholder (block 1403).

The masking of block 1402 and the etching of block 1403 are illustrated in FIG. 15. As shown in the left-side image 1550 of FIG. 15, the substrate 1501 includes recesses in which placeholders 1502 are disposed, FET stacks 1503 are formed on the substrate 1501 to define S/D regions 1504 and 1505 with buffers 1506 and epitaxy 1507 and CA contacts 1508 are formed on the FET stacks 1503. A mask 1510 is disposed over S/D region 1504, leaving S/D region 1505 unmasked. As shown in the right-side image 1551 of FIG. 15, the epitaxy 1507 of the S/D region 1505 and the corresponding placeholder 1502 are removed by etching. The corresponding placeholder 1502 of S/D region 1504 remains intact as a plug 1520.

As shown in FIG. 14, the fabrication method 1400 can further include growing buffers formed of doped semiconductor material on the channels to protrude into the unmasked one of the S/D regions (block 1404), filling the unmasked one of the S/D regions with a metalloid to be disposed in contact with corresponding ones of the buffers formed in block 1404 (block 1405) and disposing a metallic contact in backside contact with the metalloid (block 1406) as described above with reference to FIGS. 10 and 11. The fabrication method 1400 can also include unmasking the one of the S/D regions to expose the epitaxy therein (block 1407), depositing a conductive liner in a contact trench at a frontside of the epitaxy (block 1408) and filling a remainder of the contact trench with an elemental metal to form an elemental metallic contact at the frontside of the epitaxy (block 1409) as well as depositing a liner in a contact trench at a frontside of the metalloid (block 1410) and filling a remainder of the contact trench with low-k dielectric material (block 1411).

The filling of block 1405 can be executed by reflowing the metalloid (block 14051). The disposing of the metallic contact in the backside contact with the metalloid of block 1406 can include forming a wrap-around backside contact with the metalloid by replacing the substrate with a new material, such as a carrier substrate (block 14061), etching the new material to form a cavity exposing multiple surfaces of a backside end of the metalloid (block 14062) and filling the cavity with an elemental metal to form an elemental metallic contact (block 14063).

The depositing of the conductive liner of block 1408, the filling of the remainder of the contact trench with the elemental metal to form the elemental metallic contact of block 1409, the depositing of the liner in the contact trench at the frontside of the metalloid of block 1410, filling of the remainder of the contact trench with the low-k dielectric material of block 1411 and the processes associated with the disposing of the metallic contact in the backside contact with the metalloid of block 1406 will be described further below with reference to FIGS. 16 and 17.

As noted above, with reference to FIGS. 16 and 17, additional details of the fabrication method 1200 of FIG. 12 and the fabrication method 1400 of FIG. 14 are shown. It is to be understood that FIGS. 16 and 17 are generally directed to the embodiments illustrated in FIGS. 14 and 15 with the plug 1520 remaining intact as the relevant details of FIGS. 16 and 17 apply as well to the embodiments illustrated in FIGS. 12 and 13.

As shown in FIG. 16, conductive liner 1601 is deposited in a contact trench 1602 over the epitaxy 1603 of S/D region 1604 with a remainder of the contact trench 1602 filled with an elemental metal 1605 to form the elemental metallic contact. Also as shown in FIG. 16, liner 1606 is formed in contact trench 1607 at the frontside of the metalloid 1608 and a remainder of the contact trench 1607 is filled with low-k dielectric material 1609 of S/D region 1610.

After flipping the structure in order to process the backside, as shown in the left-side image 1750 of FIG. 17, substrate 1620 (see FIG. 16) is replaced with a new material, such as a carrier substrate 1701. The carrier substrate is masked by mask 1702 and etched to form a cavity 1703. This cavity exposes multiple surfaces of a backside end 1704 of metalloid 1705. As shown in the right-side image 1751 of FIG. 17, the cavity 1703 is filled with an elemental metal 1706 to form an elemental metallic contact for subsequent contact with a BSPDN.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect.

Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration. ” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc.

The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the disclosure, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A field effect transistor (FET) structure, comprising:
an FET stack comprising channels;
source/drain (S/D) regions defined on opposite sides of the FET stack;
buffers formed of doped semiconductor material disposed in contact with the channels and to protrude into each of the S/D regions;
one of epitaxy and a first metalloid disposed in a first one of the S/D regions in contact with corresponding ones of the buffers;
a plug disposed in backside contact with the one of epitaxy and the first metalloid;
a second metalloid disposed in a second one of the S/D regions in contact with corresponding ones of the buffers;
a first metallic contact disposed in frontside contact with the one of epitaxy and the first metalloid; and
a second metallic contact in backside contact with the second metalloid.

2. The FET structure according to claim 1, wherein:
the first and second metalloids are reflowable,
the first and second metalloids are conductive, and
the first and second metalloids are non-miscible with and do not form a silicide with the doped semiconductor material.

3. The FET structure according to claim 1, wherein:
the doped semiconductor materials of the buffers are doped with one of first and second dopants, and
the first and second metalloids each comprise one or more of a group III material, a group IV material and a group V material.

4. The FET structure according to claim 1, wherein:
the doped semiconductor materials of the buffers are doped with one of first and second dopants, and
the first and second metalloids each comprise one or more of tin, tin alloy, antimony, aluminum-based compounds, aluminum diboride and indium.

5. The FET structure according to claim 1, wherein the plug comprises a low-k dielectric.

6. The FET structure according to claim 1, wherein the plug comprises silicon-germanium.

7. The FET structure according to claim 1, wherein the first and second metallic contacts each comprise an elemental metal.

8. The FET structure according to claim 1, wherein the second metallic contact forms a wrap-around backside contact with the second metalloid.

9. The FET structure according to claim 1, further comprising:
a low-k dielectric and a dielectric liner interposed between the low-k dielectric and a frontside of the second metalloid; and
a contact liner interposed between the one of the epitaxy and the first metalloid and the first metallic contact.

10. A fabrication method for a field effect transistor (FET) structure, the method comprising:
etching into a substrate to form cavities in source/drain (S/D) regions defined on opposite sides of an FET stack comprising channels on the substrate;
filling the cavities with plugs;
growing buffers formed of doped semiconductor material on the channels to protrude into the S/D regions;
filling the S/D regions with epitaxy;
masking one of the S/D regions;
etching the epitaxy and the one of the plugs in another one of the S/D regions;
filling the another one of the S/D regions with a metalloid to be disposed in contact with corresponding ones of the buffers;
unmasking the one of the S/D regions;
disposing a first metallic contact in frontside contact with the epitaxy; and
disposing a second metallic contact in backside contact with the metalloid.

11. The fabrication method according to claim 10, wherein the filling comprises reflowing the metalloid.

12. The fabrication method according to claim 10, wherein:
the doped semiconductor materials of the buffers are doped with one of first and second dopants, and
the metalloid comprises one or more of a group III material, a group IV material and a group V material.

13. The fabrication method according to claim 10, wherein:
the doped semiconductor materials of the buffers are doped with one of first and second dopants, and
the metalloid comprises one or more of tin, tin alloy, antimony, aluminum-based compounds, aluminum diboride and indium.

14. The fabrication method according to claim 10, wherein the plugs comprise a low-k dielectric.

15. The fabrication method according to claim 10, wherein the plugs comprise silicon-germanium.

16. The fabrication method according to claim 10, further comprising:
depositing a liner in a contact trench at a frontside of the metalloid; and
filling a remainder of the contact trench with low-k dielectric material.

17. The fabrication method according to claim 10, wherein the disposing of the first metallic contact in the frontside contact with the epitaxy comprises:
depositing a conductive liner in a contact trench at a frontside of the epitaxy; and
filling the contact trench with an elemental metal to form an elemental metallic contact.

18. The fabrication method according to claim 10, wherein the disposing of the second metallic contact in the backside contact with the metalloid comprises forming a wrap-around backside contact with the metalloid.

19. The fabrication method according to claim 10, wherein the disposing of the second metallic contact in the backside contact with the metalloid comprises:
replacing the substrate with a new material;
etching the new material to form a cavity exposing a backside end of the metalloid; and
filling the cavity with an elemental metal to form an elemental metal contact.

20. A fabrication method for a field effect transistor (FET) structure, the method comprising:
etching into a substrate to form substrate cavities in source/drain (S/D) regions defined on opposite sides of an FET stack comprising channels on the substrate;
filling the substrate cavities with plugs;
growing buffers formed of doped semiconductor material on the channels to protrude into the S/D regions;
filling the S/D regions onto the plugs with epitaxy;
masking one of the S/D regions;
etching the epitaxy and the one of the plugs in another one of the S/D regions;
filling the another one of the S/D regions with a metalloid to be disposed in contact with corresponding ones of the buffers;
unmasking the one of the S/D regions;
disposing a first metallic contact in frontside contact with the epitaxy; and
disposing a second metallic contact in backside contact with the metalloid.
